(19) United States
(12) Patent Application Publication
(10) Pub. No.: US 2024/0121796 A1
(43) Pub. Date: Apr. 11, 2024

(54) METHODS, WIRELESS DEVICE AND NETWORK NODE FOR EFFICIENT USAGE OF DOWNLINK TRANSMISSION RESOURCES

(71) Applicant: Telefonaktiebolaget LM Ericsson (PUBL), Stockholm (SE)

(72) Inventors: Sairamesh Nammi, Austin, TX (US); Muhammad Ali Kazmi, Sundbyberg (SE)

(21) Appl. No.: 18/264,901

(22) PCT Filed: Feb. 11, 2021
(86) PCT No.: PCT/SE2021/050106

§ 371 Date: Aug. 9, 2023

(51) Int. Cl. H04W 72/232; H03M 13/13; H04L 1/00; H04L 1/1607

(52) U.S. Cl. CPC H04W 72/232; H03M 13/13; H04L 1/0043; H04L 1/1671

(57) ABSTRACT

Disclosed is a method performed by a network node (130) of a wireless communication network (100) for efficient usage of downlink transmission resources. The method comprises transmitting, to a wireless device (140), an encoded first control data packet on a downlink control channel using a first level of a transmission parameter, and receiving, from the wireless device (140), information on decoding status for the first control data packet transmitted on the downlink control channel using the first transmission parameter level, the decoding status being a quantitative measure of decoding complexity of the wireless device in decoding the first control data packet. The method further comprises transmitting, to the wireless device (140), an encoded second control data packet on the downlink control channel using a second level of the transmission parameter, the second level being determined based on the received information on decoding status.

### TECHNICAL FIELD

The present disclosure relates generally to methods, wireless devices and network nodes for efficient usage of downlink transmission resources. The present disclosure further relates to computer programs and carriers corresponding to the above methods, devices and nodes.

### BACKGROUND

To meet the huge demand for data centric applications, there is an ongoing evolution of fourth Generation (4G) wireless communication networks such as Long-Term Evolution (LTE), into fifth Generation (5G) wireless communication networks, also called New Radio (NR) access. The following are some of the requirements for the 5G networks: Data rates of several tens of megabits per second should be supported for tens of thousands of wireless devices; 1 gigabit per second to be offered simultaneously to tens of workers on the same office floor; Several hundreds of thousands of simultaneous connections to be supported for massive sensor deployments, aka Internet of Things (IoT) devices; Spectral efficiency should be significantly enhanced compared to 4G; Coverage should be improved compared to 4G; Signaling efficiency should be enhanced compared to 4G, and latency should be reduced significantly compared to 4G.

It is well known that Multiple Input Multiple Output (MIMO) systems can significantly increase the data carrying capacity of wireless communication networks, aka wireless networks. For this reason, MIMO systems are an integral part of the 3G and 4G wireless networks. 5G wireless networks will also employ MIMO systems; in 5G they are called massive MIMO systems. A massive MIMO system signifies a size of hundreds of antennas at the transmitter side and/or the receiver side, or even more. Typically, with Nₜ denoting the number of transmitter antennas and Nᵣ denoting the number of receiver antennas, the peak data rate multiplies with a factor of Nₜ compared to single antenna systems in a rich scattering environment.

FIG. 1 shows a typical message sequence chart for downlink data transfer in wireless networks, here exemplified with a message sequence chart of a 5G network. A gNodeB (gNB) 30 sends 1.1 pilot or reference signals towards a wireless device aka User Equipment (UE) 40. From the pilot or reference signals, the UE 40 determines the channel estimates and then determines 1.2 Channel State Information (CSI) parameters. The UE 40 sends 1.3 the CSI parameter to the gNB 30 over a feedback channel, i.e., an uplink control channel. The CSI parameters are sent 1.3 in a CSI report. The CSI parameters comprises one or more of channel quality indicator (CQI), precoding matrix index (PMI), rank information (RI), CSI-Reference Signal (CSI-RS) Resource Indicator (CRI), which can be the same as beam indicator, Layer Indicator (LI) etc. The CSI report is sent 1.3 either on request from the network a-periodically or the UE is configured to report periodically. A network scheduler in the gNB 30 uses the CSI parameters for determining 1.4 downlink (DL) transmission parameters, such as parameters for scheduling of this particular UE, Modulation and Coding Scheme (MCS), Physical Resource Blocks (PRBs) and transmission power to use by the UE. The gNB 30 sends 1.5 the scheduling parameters to the UE 40 in a downlink control channel. After that actual data transfer 1.6 takes place from the gNB 30 to the UE 40 over a data traffic channel.

The uplink control channel may, apart from being used for sending the CSI parameters, be carrying Hybrid Automatic Repeat Request Acknowledgements (HARQ-ACK) information corresponding to downlink data transmission over the data traffic channel. The CSI can be divided into two categories, where one is for sub band and the other for wideband. The configuration of sub-band or wideband CSI reporting is done through Radio Resource Control (RRC) signaling as part of CSI reporting configuration. The uplink control channel may be a Physical Uplink Control Channel (PUCCH).

The downlink control channel (DCI), such as Physical Downlink Control Channel (PDCCH), carries control data packets, aka packets comprising control information, such as information about scheduling grants and assignments. Typically, this control information comprises one or more of number of MIMO layers scheduled, transport block sizes, modulation for each codeword, parameters related to HARQ, sub-band locations etc. In general, the contents of the DCI depend on transmission mode and DCI format. Typically, one or more of the following information may be transmitted over the DCI using different DCI formats: Carrier indicator; Identifier for DCI formats; Bandwidth part indicator; Frequency domain resource assignment; Time domain resource assignment; Virtual Resource Block (VRB)-to-Physical Resource Block (PRB) mapping flag; PRB bundling size indicator; Rate matching indicator; Zero Power (ZP) CSI-RS trigger; MCS for each Transport Block (TB); New data indicator for each TB; Redundancy version for each TB; HARQ process number; Downlink Assignment Index; Transmit Power Control (TPC) command for uplink control channel; PUCCH resource indicator; Physical Downlink Shared Channel (PDSCH)-to-HARQ feedback timing indicator; Antenna port(s); Transmission configuration indication; Sounding Reference Signal (SRS) request, Code Block Group (CBG) transmission information CBG flushing out information, and Demodulation Reference Signal (DMRS) sequence initialization.

A control channel resource set (CORESET) is a time-frequency resource in which the wireless device tries to decode candidate downlink control channels using one or more search spaces. The size and location of a CORESET is semi statistically configured by the network node and thus can be set smaller than the carrier bandwidth. A first CORESET, CORESETO is provided by a master information block (MIB) as part of the configuration of the initial bandwidth part to be able receive remaining system information and additional configuration information from the network node. After connection setup, the wireless device can be configured with multiple, potentially overlapping, CORESETs using RRC signaling.

In the time domain, a CORESET can be up to 3 Orthogonal Frequency Division Multiplex (OFDM) symbols in duration and located anywhere within a slot. Note that the CORESET is defined from the device perspective, and only indicates where the wireless device may receive PDCCH transmissions. It does not say anything on whether the network node, e.g., gNB actually transmits a PDCCH or not. In the frequency domain, a CORESET is defined in multiples of 6 resource blocks up to the carrier bandwidth. FIG. 2 shows an example of CORESET configuration in one time slot. Note that in this example there are 4 CORESET configurations where CORESET configurations #1 and #3 overlap with each other.

Going back to FIG. 1 and to the content of the downlink control channel, it can be understood that it is of utmost importance for both downlink and uplink communication that the information of the control channel is communicated properly, in other words that the data packets of the control channel is correctly received and decoded. Hence it is recommended to use a robust channel coding scheme to protect the information bits. For encoding the information bits, Polar code was chosen in NR as the channel code Polar code will also be considered for 6G networks.

The Polar code construction at an encoder, i.e., at a transmitter, is divided into 4 stages as shown in FIG. 3. Given an information block length of K, which includes Cyclic Redundancy Check (CRC), and a code block length, i.e. codeword, of N, the first step is to determine 52 the number of frozen bit locations, which is N-K. This is because according to polarization theory, the reliability of each location is different from each other. The locations with the highest reliability are chosen to transmit the information bits to the receiver.

In the second stage the values for the frozen bits and the information bits are set 54. In general, it is common to use zeros for the frozen bits as they are less reliable. Note that the locations of the frozen bits and the values of the frozen bits are known to both the transmitter and the receiver. In general, it is common to set the number of frozen and information bit locations set to 2NP, where Np is the number of output bits of the polar encoder. In the third stage, the encoding 56 of the information including frozen bits and non-frozen bits are passed to the polar encoder, i.e., a polar matrix. In the fourth stage, rate matching 58 is performed, i.e., the N bit codeword is shortened or extended into M-sized code length by puncturing or adding bits.

FIG. 4 shows the decoding part of the Polar code, i.e., at a decoder of a receiver after reception on a radio interface. Here list decoding 62 is performed to form a set of predefined candidates and the bits are selected 64 from the candidate codeword once the candidate codeword is found. The candidate codeword selected from the predefined candidates may be selected as the codeword that gives minimum Euclidean distance with the received signal.

In addition, similar to previous generations such as 4G LTE networks and 3G High Speed Packet Access (HSPA) networks for encoding of downlink control channel, the information block is appended with a 24 bits CRC that is masked with a UE ID, i.e. Radio Network Temporary Identifier (RNTI), i.e., as an exclusive-or (XOR) operation of the CRC bits and the RNTI. That is, the UE ID is not explicitly transmitted, but by including the UE ID when calculating the CRC at the receiver, the UE can determine from the CRC masked with the UE ID whether it was the intended recipient or not. If the transmission is intended for another UE, the CRC will not check. Once the polar code is constructed as shown in FIG. 3, the resources are mapped to the OFDM time-frequency grid and transmitted.

A wireless device in an NR, that is, a 5G network, needs to monitor up to 4 DCI sizes in the configured CORESETS. One size is used for a fall back DCI, one for scheduling downlink grants, one for scheduling uplink grants and one for slot format indication and pre-emption indication depending on the configuration. Each downlink control channel needs to be decoded using any of aggregation levels 1, 2, 4, 8, or 16. The higher aggregation level the more resources is given for coded bits. In other words, the code rate is inversely proportional to the aggregation level. To limit the wireless device complexity in searching all the CORESETS and for all the aggregation levels, there are defined search spaces in NR networks. A search space is a set of candidate control channels formed by CORESETS at a given aggregation level, which the wireless device is supposed to attempt to decode. As there are multiple CORESETS, there are multiple search spaces. In NR networks, at most 10 search spaces can be configured for each device. It can be observed that the network needs to indicate the search space and the corresponding aggregation level to the device. In general, it is common practice to configure the aggregation level for a given CORESET to a fixed value.

As shown, lots of wireless communication resources between the network and the wireless device are used for the transmission of control data over the downlink control channel. It would be of interest to more efficiently use the wireless communication resources so that more transmission resources can be used for sending traffic data instead of sending control data. At the same time, it needs to be secured that the control data sent over the downlink control channel are safely received and correctly interpreted at the wireless device.

### SUMMARY

It is an object of the invention to address at least some of the problems and issues outlined above. It is possible to achieve these objects and others by using methods, network nodes and wireless devices as defined in the attached independent claims.

According to one aspect, a method is provided that is performed by a network node of a wireless communication network for efficient usage of downlink transmission resources. The method comprises transmitting, to a wireless device, an encoded first control data packet on a downlink control channel using a first level of a transmission parameter. The method further comprises receiving, from the wireless device, information on decoding status for the first control data packet transmitted on the downlink control channel using the first transmission parameter level, the decoding status being a quantitative measure of decoding complexity of the wireless device in decoding the first control data packet. The method further comprises transmitting, to the wireless device, an encoded second control data packet on the downlink control channel using a second level of the transmission parameter, the second level being determined based on the received information on decoding status.

According to another aspect, a method is provided that is performed by a wireless device connected to a wireless communication network. The method comprises receiving, from a network node of the wireless communication network, an encoded first control data packet on a downlink control channel, the first control data packet being transmitted by the network node with a first level of a transmission parameter, transmitting, to the network node, information on decoding status for the first control data packet received on the downlink control channel, the decoding status being a quantitative measure of decoding complexity of the wireless device in decoding the first control data packet, and receiving, from the network node, an encoded second control data packet on the downlink control channel, the second control data packet being transmitted by the network node with a second level of the transmission parameter, the second level being based on the transmitted information on decoding status.

According to another aspect, a network node is provided, which is operable in a wireless communication network and configured for efficient usage of downlink transmission resources. The network node comprises a processing circuitry and a memory. Said memory contains instructions executable by said processing circuitry, whereby the network node is operative for transmitting, to a wireless device, an encoded first control data packet on a downlink control channel using a first level of a transmission parameter, and receiving, from the wireless device, information on decoding status for the first control data packet transmitted on the downlink control channel using the first transmission parameter level, the decoding status being a quantitative measure of decoding complexity of the wireless device in decoding the first control data packet. The network node is further operative for transmitting, to the wireless device, an encoded second control data packet on the downlink control channel using a second level of the transmission parameter, the second level being determined based on the received information on decoding status.

According to another aspect, a wireless device is provided that is configured for connection to a wireless communication system. The wireless device comprises a processing circuitry and a memory. Said memory contains instructions executable by said processing circuitry, whereby the wireless device is operative for receiving, from a network node of the wireless communication network, an encoded first control data packet on a downlink control channel, the first control data packet being transmitted by the network node with a first level of a transmission parameter, and transmitting, to the network node, information on decoding status for the first control data packet received on the downlink control channel, the decoding status being a quantitative measure of decoding complexity of the wireless device in decoding the first control data packet. The wireless device is further operative for receiving, from the network node, an encoded second control data packet on the downlink control channel, the second control data packet being transmitted by the network node with a second level of the transmission parameter, the second level being based on the transmitted information on decoding status.

According to other aspects, computer programs and carriers are also provided, the details of which will be described in the claims and the detailed description.

Further possible features and benefits of this solution will become apparent from the detailed description below.

### BRIEF DESCRIPTION OF DRAWINGS

The solution will now be described in more detail by means of exemplary embodiments and with reference to the accompanying drawings, in which:

FIG. 1 is a signaling diagram in a wireless communication network, according to the prior art.

FIG. 2 is a Cartesian coordinate system illustrating an example of CORESETs spread out in time and frequency, according to prior art.

FIG. 3 is a flow chart of Polar encoding performed by an encoder, according to prior art.

FIG. 4 is a flow chart of Polar decoding performed by a decoder, according to prior art.

FIG. 5 is a block diagram illustrating a wireless communication network in which the present invention may be used.

FIG. 6 is a flow chart illustrating a method performed by a network node, according to possible embodiments.

FIG. 7 is a flow chart illustrating a method performed by a wireless device, according to possible embodiments.

FIG. 8 is a diagram illustrating Block Error Rate (BLER) in relation to SNR for different Aggregation Levels (AL).

FIG. 9 is a signaling diagram illustrating an example of a procedure, according to further possible embodiments.

FIG. 10 is a block diagram illustrating a network node in more detail, according to further possible embodiments.

FIG. 11 is a block diagram illustrating a wireless device in more detail, according to further possible embodiments.

### DETAILED DESCRIPTION

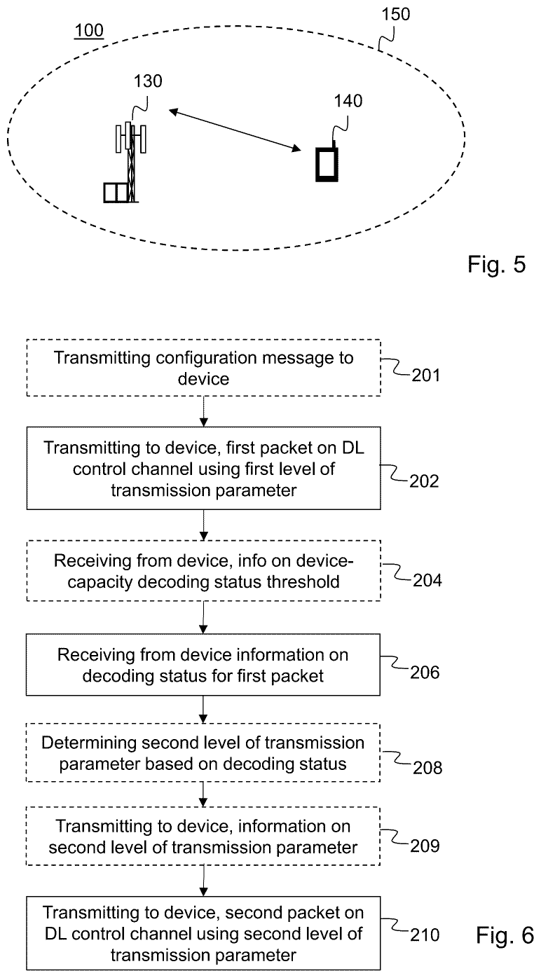

FIG. 5 shows a wireless communication network 100 comprising a radio access network (RAN) node aka network node 130 that is in, or is adapted for, wireless communication with a wireless communication device aka wireless device 140. The network node 130 provides radio access in a geographical area called a cell 150.

The wireless communication network 100 may be any kind of wireless communication network that can provide radio access to wireless devices. Example of such wireless communication networks are networks based on Global System for Mobile communication (GSM), Enhanced Data Rates for GSM Evolution (EDGE), Universal Mobile Telecommunications System (UMTS), Code Division Multiple Access 2000 (CDMA 2000), Long Term Evolution (LTE), LTE Advanced, Wireless Local Area Networks (WLAN), Worldwide Interoperability for Microwave Access (WiMAX), WiMAX Advanced, as well as fifth generation (5G) wireless communication networks based on technology such as New Radio (NR), and any possible future sixth generation (6G) wireless communication network.

The network node 130 may be any kind of network node that can provide wireless access to a wireless device 140 alone or in combination with another network node. Examples of network nodes 130 are a base station (BS), a radio BS, a base transceiver station, a BS controller, a network controller, a Node B (NB), an evolved Node B (eNB), a gNodeB (gNB), a Multi-cell/multicast Coordination Entity, a relay node, an access point (AP), a radio AP, a remote radio unit (RRU), a remote radio head (RRH) and a multi-standard BS (MSR BS).

The wireless device 140 may be any type of device capable of wirelessly communicating with a network node 130 using radio signals. For example, the wireless device 140 may be a User Equipment (UE), a machine type UE or a UE capable of machine to machine (M2M) communication, a sensor, a tablet, a mobile terminal, a smart phone, a laptop embedded equipped (LEE), a laptop mounted equipment (LME), a USB dongle, a Customer Premises Equipment (CPE) etc.

FIG. 6, in connection with FIG. 5, shows a method performed by a network node 130 of a wireless communication network 100 for efficient usage of downlink transmission resources. The method comprises transmitting 202, to a wireless device 140, an encoded first control data packet on a downlink control channel using a first level of a transmission parameter. The method further comprises receiving 206, from the wireless device 140, information on decoding status for the first control data packet transmitted on the downlink control channel using the first transmission parameter level, the decoding status being a quantitative measure of decoding complexity of the wireless device in decoding the first control data packet. The method further comprises transmitting 210, to the wireless device 140, an encoded second control data packet on the downlink control channel using a second level of the transmission parameter, the second level being determined based on the received information on decoding status.

By such a method, the transmission parameter for transmitting control data packets on the downlink control channel can be adapted to the situation for the wireless device when decoding the first control data packet transmitted on the downlink control channel. In other words, the transmission parameter, such as transmission power and/or an encoding parameter can be adapted to decoding complexity of the wireless device in decoding the first control data sent by the network node on the downlink control channel, i.e., how difficult it was for the wireless device to decode the first control data. As a result, the amount of downlink transmission resources used for transmitting data on the downlink control channel is adapted to the channel conditions so that when there are good downlink transmission conditions towards the wireless device, i.e., easy to decode the control data packets, less transmission resources are used for the downlink control channel. Such spared transmission resources can instead be used for other purposes, such as for downlink traffic data transmission. As a result, downlink throughput and network throughput can be significantly improved, especially when there are good downlink transmission conditions, without risking data quality on the downlink control channel.

A “control data packet” transmitted on the downlink control channel may comprise downlink (DL) control information (DCI), such as information about uplink (UL) scheduling grants and DL scheduling assignments. The downlink control channel may be a Physical Downlink Control Channel (PDCCH). The control data packet may also be called control transport block or control data block. “Transmission parameter” may be transmission power, or one or more encoding parameters such as aggregation level, precoding vector, and number of candidate codewords used for encoding the control data packet. The transmission parameter may be one or more such parameters. The first level of the transmission parameter may be any level used for transmitting the first control data packet, in contrast to the second level, which is used for transmitting the second control data packet. The first level may be a default level. In case the transmission parameter is an encoding parameter such as aggregation level, the first level may have been informed to the wireless device before the first transmission step 202. The second level may be the same or a different level than the first level. When the received information on decoding status indicates that it is necessary to increase the transmission parameter in order to get a better decoding status, the second level is determined higher than the first level, and vice versa. “Higher” here means a more complex encoding or a higher transmission power. The “quantitative measure of decoding complexity” may be one or more of: which decoding type that was used, list size, number of computations performed, such as additions or multiplications, and number of candidate codewords that was used by the wireless device to decode the first control data packet.

According to an embodiment, the method further comprises determining 208 the second level of the transmission parameter based on the received information on decoding status.

According to an embodiment, the method further comprises encoding the first and second control data packet.

According to another embodiment, the transmission parameter is an encoding parameter used for the encoding of the first and second control data packet. By sending the second control data packet with a second level of the encoding parameter that is based on the qualitative measure of the decoding complexity at the wireless device, i.e., how difficult it was for the wireless device to decode the encoded first control data packet transmitted with first level of the encoding parameter, the second level of the encoding parameter, such as aggregation level, can be adapted to the decoding complexity. As a result, transmission resources for transmission of DCC can be adapted to decoding complexity and more resources can be used for DL transmission of traffic data when there are good transmission/decoding conditions.

According to an alternative of this embodiment, the second level of the encoding parameter is different from the first level of the encoding parameter. Further, the method comprises, prior to the transmitting 210 of the encoded second control data packet on the downlink control channel using the second level of the encoding parameter, transmitting 209 information on the second level of the encoding parameter to the wireless device 140. Hereby, the wireless device knows the new encoding parameter level such as aggregation level before the second control data packet is sent and the wireless device can hereby decode the second control data packet. This may be needed when the transmission parameter is an encoding parameter, and its second level is different from the first level. The information on the second level of the encoding parameter may be sent using higher layer signaling, such as RRC or Media Access Control (MAC), higher layer in the OSI-model compared to DCC which is on the physical layer.

According to another embodiment, the received 206 information on decoding status is information on list size, which is a number of candidate codewords that was used by the wireless device 140 for decoding the first control data packet. The information on list size is then used by the network node to determine a second level of the transmission parameter, such as aggregation level. For example, if the information on list size shows that only a few candidate codewords was used out of the number of codewords of the aggregation level used for sending the first control data packet, the aggregation level used by the network node can be lowered when sending the second control data packet compared to sending the first control data packet.

According to an alternative, the received information on list size is a bit value referring to a decoder status list look-up table with different bit values and corresponding list sizes and/or decoder types, which look-up table is obtainable by both the wireless device 140 and the network node 130. Hereby, only a bit value needs to be sent uplink for identifying list size instead of having to send explicit information of the list size. Thus, UL transmission resources can be spared. In one example the decoder status list look-up table can be pre-defined in the wireless device 140 and/or in network node 130. In this case the look-up table is obtained by pre-configuring it in the wireless device 140 and/or in network node 130. In another example the decoder status list look-up table can be dynamically or semi-statically determined or created by the network node 130 or by another network node, e.g., based on one or more of: available resources in the network node 130, signal quality (e.g. SINR, SNR, BLER etc.) estimated at the wireless device 140 and/or at the network node 140, wireless device 140 battery life status (e.g. available resources) etc. In this case the network node 130 further configures the wireless device 140 with the information (e.g. as a pre-defined identifier) about the determined look-up table. In another example, multiple decoder status list look-up tables can be pre-defined or determined by the network node 130 or another network node. In this case, the wireless device 140 is configured by the network node 130 with the information, e.g. as a pre-defined identifier, about at least one of the pre-defined or determined look-up tables for indicating the wireless device 140 decoder status to the network node 130. The configuration information can be transmitted to the wireless device 140 via higher layer signaling, e.g. RRC signaling, or via lower layer signaling, e.g. via MAC, downlink control information (DCI) etc.

According to another embodiment, the information on decoding status for the first control data packet is received 206 in an uplink control channel used by the wireless device to transmit a HARQ-ACK or CSI in response to a network node transmission on a downlink traffic channel. By reusing an already used channel, no additional message needs to be sent, and UL transmission resources are efficiently used. The UL control channel may be a Physical Uplink Control Channel (PUCCH). The downlink traffic channel may be a Physical Downlink Shared Channel (PDSCH).

According to yet another embodiment, the information on decoding status for the first control data packet is received 206 in an uplink traffic channel. The uplink traffic channel may be a Physical Uplink Shared Channel (PUSCH).

According to yet another embodiment, the method further comprises transmitting 201 a configuration message to the wireless device 140 with instructions to the wireless device how to send the information on decoding status to the network node 130. The configuration message may comprise what information on decoding status to send to the network node, based on which events or conditions to send the information on decoding status, such as for each DL channel reception, for certain scheduling configurations and/or for certain changes in decoding status, whether to send composite information about decoder status for a group of DL channel receptions, in which UL channels to send the information on decoding status, at which periodicity to send the information on decoding status, etc.

According to an alternative, the instructions of the configuration message comprise a decoding status threshold and an instruction to only send the information on the decoding status when the decoding status exceeds the decoding status threshold. Hereby, the information on decoding status that is sent can be limited to e.g., occasions when there has been a significant change of decoding status since last time decoding status information was sent. Hereby communication resources are spared but important information on change of decoding status is till sent.

According to still another embodiment, the method further comprises receiving 204, from the wireless device, information on a device-capacity decoding status threshold related to which decoding status the wireless device can manage to decode. The device-capacity decoding status threshold can be regarded as a recommended maximum value of the decoding status, such as a recommended maximum value of list size. The network node can then select encoding method based on the decoding capacity of the device.

According to still another embodiment, the network node 130 has a polar encoder, and the method further comprises encoding the first and second control data packets using the polar encoder.

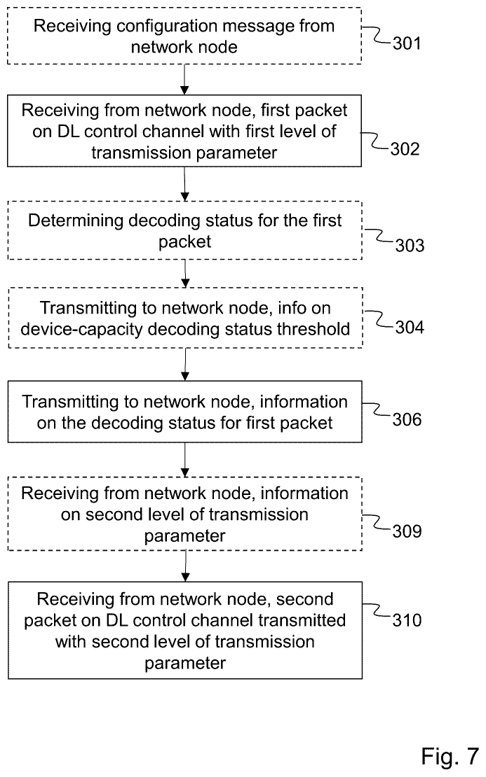

FIG. 7, in connection with FIG. 5, shows a method performed by a wireless device 140 connected to a wireless communication network 100. The method comprises receiving 302, from a network node 130 of the wireless communication network 100, an encoded first control data packet on a downlink control channel, the first control data packet being transmitted by the network node with a first level of a transmission parameter, transmitting 306, to the network node 130, information on decoding status for the first control data packet received on the downlink control channel, the decoding status being a quantitative measure of decoding complexity of the wireless device in decoding the first control data packet, and receiving 310, from the network node 140, an encoded second control data packet on the downlink control channel, the second control data packet being transmitted by the network node with a second level of the transmission parameter, the second level being based on the transmitted information on decoding status.

According to an embodiment, the method further comprises decoding the received first and second control data packet.

According to an embodiment, the method further comprises, at decoding the first control data packet, determining 303 decoding status for the first control data packet.

According to an embodiment, the transmission parameter is an encoding parameter used for the encoding of the first and second control data packet.

According to an alternative of this embodiment, the second level of the encoding parameter is different from the first level of the encoding parameter. The method further comprises, prior to the receiving 310 of the encoded second control data packet on the downlink control channel with the second level of the encoding parameter, receiving 309 information on the second level of the encoding parameter from the network node 130.

According to another embodiment, the transmitted 306 information on decoding status is information on list size, which is a number of candidate codewords that was used by the wireless device 140 for decoding the first control data packet.

According to an alternative of this embodiment, the transmitted information on list size is a bit value referring to a decoder status list look-up table with different bit values and corresponding list sizes and/or decoder types, which look-up table is obtainable by both the wireless device 140 and the network node 130.

According to yet another embodiment, the information on decoding status for the first control data packet is transmitted 306 in an uplink control channel used by for transmitting a HARQ-ACK or CSI in response to a network node transmission on a downlink traffic channel.

According to yet another embodiment, the information on decoding status for the first control data packet is transmitted 306 in an uplink traffic channel.

According to still another embodiment, the method further comprises receiving 301 a configuration message from the network node 130 with instructions to how to transmit 306 the information on decoding status to the network node 130.

According to an alternative of this embodiment, the instructions of the configuration message comprise a decoding status threshold and an instruction to only transmit the information on the decoding status when the decoding status exceeds the decoding status threshold.

According to yet another embodiment, the method further comprises transmitting 304, to the network node, information on a device-capacity decoding status threshold related to which decoding status the wireless device can manage to decode.

According to yet another embodiment, the wireless device 140 has a polar decoder, and the method further comprises decoding the first and second control data packets using the polar decoder.

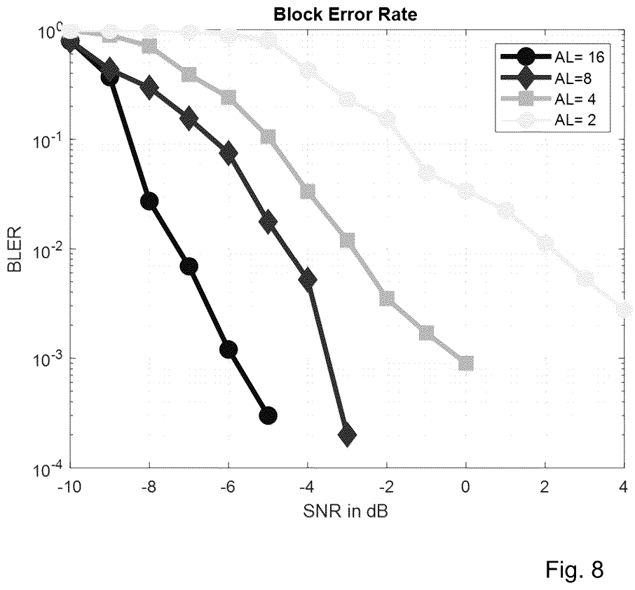

According to embodiments of the present disclosure, instead of setting one or more transmission parameters for the downlink control channel (DCC) such as aggregation level, transmission power etc. at the same value for all the CORESETS and for all the UEs in the cell as in prior art, the network node adapts the one or more transmission parameters based on feedback from each UE. As an example, FIG. 8 shows the Block Error Rate (BLER) for different aggregation levels (AL) as a function of Signal to Noise Ratio (SNR). It can be observed that the performance depends on the aggregation level and the specific SNR. That is, if the UE has good SNR conditions, the network node can use a lower aggregation level, thereby reducing the number of communication resources, i.e., time-frequency resources, needed for transmitting the DCC. However, there is no support in current standard specifications for any feedback from the UE for adapting parameters for the DCC. Accordingly, and according to this disclosure, we propose that the UE feedbacks decoding status, such as the list size used for decoding scheduled DCC. Once the network node gets this information it can adapt the one or more transmission parameters for subsequent transmissions on the DCC. The DCC could be the PDCCH.

According to an embodiment, the network node uses a default transmission parameter level, e.g., aggregation level (AL) equal to 8 for transmitting control data packets on the PDCCH. The UE decodes the transmitted control data packets received on the PDCCH using a polar decoder. Then the UE informs the network node of its decoding status, and the network node uses this information to determine transmission parameter level for subsequent transmissions of packets on the PDCCH. In the example of the network node transmitting first packets on the PDCCH with AL 8, if the UE informs the network node that it can decode the PDCCH using a minimum list size or with a reduced number of candidates codewords, then the network node uses this information and sets the AL lower than the existing AL, for example at AL 2. Similarly, if the UE sends an indication that it uses maximum list size or maximum number of candidate codewords, then the network node increases the AL higher than that of the existing AL, in the example perhaps to AL 16. Note that if the UE informs the network node of a list size of for example 4, it means the UE can decode the downlink control channel by using 4 candidate codewords.

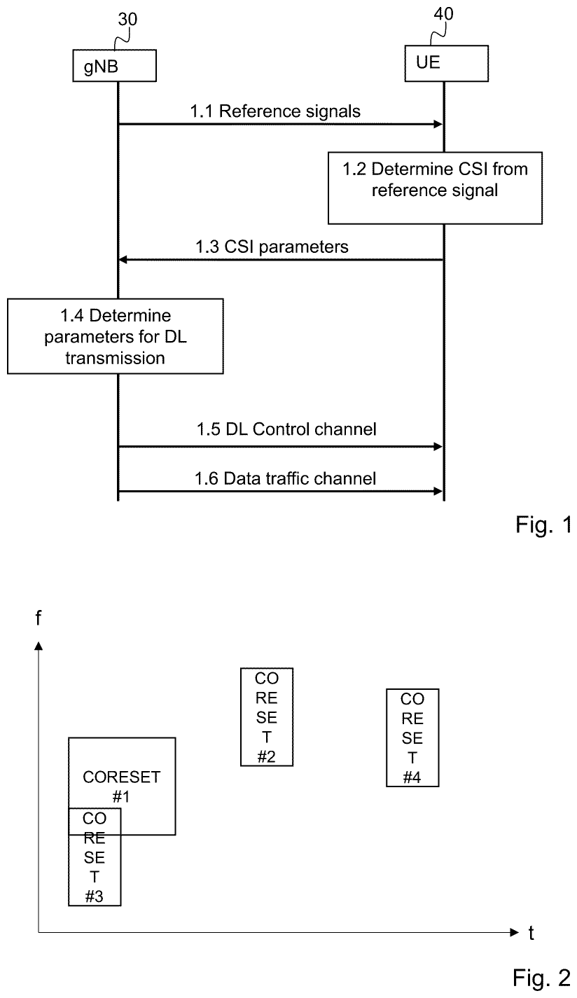

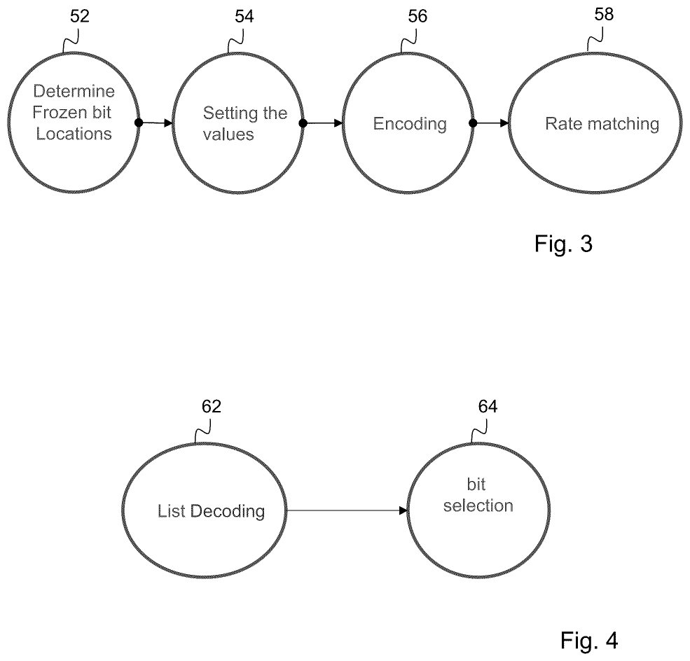

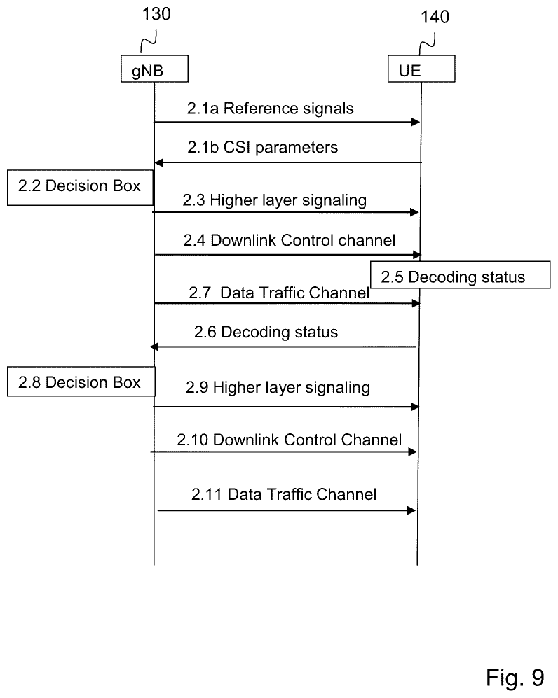

FIG. 9 shows an example of a message sequence chart for communicating between a network node 130, e.g. gNB and a wireless device 140 e.g. UE. As in prior art FIG. 1, the gNB 130 sends reference signals 2.1a to the UE 140, the UE determines CSI from the reference signals and sends information of the CSI parameters 2.1b in return. The gNB 130 then determines DL transmission parameters based on the CSI parameters in Decision box 2.2. Thereafter, the gNB may configure the UE with a first transmission parameter level, when the transmission parameter is an encoding parameter, e.g. a first aggregation level, using e.g. a higher layer signaling message 2.3 such as RRC or MAC. The gNB then transmits first control packets on the DCC 2.4 with the first transmission parameter level. The UE decodes the first control packets and determines decoding status 2.5. The UE then sends information on the decoding status 2.6 to the gNB. In the meantime, the gNB sends traffic data on a data traffic channel 2.7 to the UE. The decoding status 2.6 may be sent before receiving traffic data on the data traffic channel or after receiving on the data traffic channel. When sending the decoding status after receiving on the data traffic channel, the decoding status may be sent in an uplink feedback channel that is used already for sending feedback on the DL transmission on the data traffic channel. Further, based on the received decoding status, the gNB determines in Decision Box 2.8 a second level of the transmission parameter, e.g., a second aggregation level. When it is determined, based on the received decoder status that the first transmission parameter is to be changed, and when the transmission parameter is an encoding parameter such as aggregation level, then the gNB sends a message 2.9, e.g. using higher layer signaling such as RRC or MAC, to the UE that the second aggregation level is to be used for encoding. The gNB further sends second control packets on the DCC 2.10 using the second level of the transmission parameter. Thereafter, the gNB sends traffic data 2.11 on the data traffic channel. Except for being an encoding parameter, the transmission parameter may be transmission power. In such an embodiment, the gNB can increase or decrease the transmission power for the DCC based on the feedback of decoding status it received from the UE.

As explained above, the wireless device feedbacks the decoder status for decoding the DCC to the network node. The network node may use a polar encoder and the wireless device may use a polar decoder. The decoder status can be expressed in terms of a parameter called herein as list size. The term ‘list size’ defines number of candidate codewords, or a list of possible candidate codewords, applied or used by the UE on the packet received on the DCC for successfully decoding the packet. The term packet herein may correspond to a set of encoded bits encoded by the network node with certain modulation and coding scheme e.g. Quadrature Phase Shift Keying (QPSK) and/or Polar code with certain code rate. Examples of a packet are code block, data block, transport block etc. There are multiple methods for the wireless device to inform the network node of the determined decoder status. For example, if the wireless device is able to decode the downlink control channel without list decoder such as successive cancellation (SC) decoder, then the wireless device can inform the decoder status as lowest list size (e.g. 2). In another embodiment, if the wireless device uses a list decoder and uses a list size of 8 then it can indicate this information to the network node. One exemplary method to transmit the decoder status is shown in Table 2. In another example one of the decoder status can be defined as a default decoder used by the wireless device, e.g. an SC decoder. In this case, if the wireless device does not signal the decoder status, then the network node assumes that the wireless device is applying certain default decoder, e.g. SC decoder. This example is shown in Table 3. In yet another example, the wireless device explicitly signals the status for any possible decoder used by the wireless device. This example is shown in Table 4. As described in preceding embodiments, one or a plurality of the look-up tables (e.g. any one or more of tables 1-4) can be pre-defined and/or determined by the network node. In case of multiple look-up tables, the wireless device 140 is further configured with the information about the look-up table to be used by the wireless device 140 for signaling its decoder status to the network node 130.

TABLE 2
A first example of information about wireless device
decoder status signaled to the network node.

| | Number of candidate codewords | Indicated |
|---|---|---|
| Decoder status | used for decoding packet (Np) | value |
| SC decoder or list size 2 | Np ≤ 2 | 000 |
| List size 4 | 2 < Np ≤ 4 | 001 |
| List size 8 | 4 < Np ≤ 8 | 010 |
| List size 16 | 8 < Np ≤ 16 | 011 |
| List size 32 | 16 < Np ≤ 32 | 100 |

TABLE 3
A second example of information about wireless
device decoder status signaled to network node

| | Number of candidate codewords | Indicated |
|---|---|---|
| Decoder status | used for decoding packet (Np) | value |
| SC decoder^{Note} | NA | None |
| List size 2 | Np ≤ 2 | 000 |
| List size 4 | 2 < Np ≤ 4 | 001 |
| List size 8 | 4 < Np ≤ 8 | 010 |
| List size 16 | 8 < Np ≤ 16 | 011 |
| List size 32 | 16 < Np ≤ 32 | 100 |

^{Note}
Default assumption i.e. if UE does not signal its decoder status

TABLE 4
A third example of information about wireless
device decoder status signaled to network node.

| | Number of candidate codewords | Indicated |
|---|---|---|
| Decoder status | used for decoding packet (Np) | value |
| SC decoder | NA | 0000 |
| list size 2 | Np ≤ 2 | 0001 |
| List size 4 | 2 < Np ≤ 4 | 0010 |
| List size 8 | 4 < Np ≤ 8 | 0011 |
| List size 16 | 8 < Np ≤ 16 | 0100 |
| List size 32 | 16 < Np ≤ 32 | 0101 |

Once the wireless device determines the decoder status to be indicated, it has to convey this information to the network node. According to an embodiment, this information on decoder status is sent using an uplink control channel that is used to transmit the HARQ-ACK of PDSCH. In another embodiment, the wireless device can send this information using a physical uplink shared channel (PUSCH). The wireless device can further be configured by the network node with one or more parameters or configurations to be used by the wireless device for transmitting the information about the decoder status of the wireless device. Examples of such parameters or configurations are explained below.

In one example, the wireless device may be configured to transmit information about the decoder status for each DL channel reception.

In another example, the wireless device may be configured to transmit information about the decoder status for a specific DL channel reception, e.g. one with certain scheduling configuration such as the one scheduled with MCS higher than a threshold.

In another example, the wireless device may be configured to transmit aggregated or composite or overall information about the decoder status for a group of DL channel receptions e.g. average of the decoder status for K number of DL channel receptions, maximum list size used for decoding K number of DL channel receptions, where K is at least 2.

In another example, the wireless device may be configured whether to transmit the decoder status in every UL control channel or not. In the latter case the wireless device may further be configured with a condition under which and/or a periodicity with which the wireless device may transmit its decoder status to the network node. An example of condition is a change in list size by a certain threshold. For example, the wireless device may report the decoder status only when the decoder status changes by at least certain margin e.g. from size 4 to 8 between two decoding attempts, which may be successive or any two over a certain time period.

In another example the network node configures the wireless device with a threshold (G) expressed in terms of the list size. The wireless device compares the determined parameter, Np, with the threshold G, and based on the comparison the wireless device decides whether to transmit information about the decoder status or not. In one example, the threshold G corresponds to a maximum number of candidate codewords, and the wireless device upon exceeding the threshold, is required to transmit the information about the decoder status to the network node. For example, if Np>G then the wireless device transmits information about the decoder status; otherwise, it does not transmit information about the decoder status.

Note that the wireless device can send this information explicitly, that is in separate fields, or implicitly, which means that the indicated value is part of an already sent information, such as the HARQ-ACK of the PDSCH. As described, the network node uses the received information about the decoder status of the wireless device for adapting one or more transmission parameters, i.e., transmission power or an encoding parameter for encoding the channel e.g., aggregation level etc.

According to another embodiment, the wireless device transmits to the network node, information about a second threshold (H) related to a decoder status that the wireless device can manage for decoding the data on the DCC. The wireless device may further transmit information about the decoder status of the DL channel reception. The second threshold H can be regarded as a recommended value of the maximum value of the list size. The second threshold H can be expressed in terms of list size as expressed in examples in Tables 2-4. The second threshold H may indicate the maximum number of candidate codewords which the wireless device can manage for decoding the channel. For example, if the number of candidate codewords for decoding the packet (Np) exceeds the second threshold H, then the wireless device power consumption may increase above an acceptable threshold; otherwise the wireless device power consumption remains within an acceptable threshold. In another example if Np exceeds the second threshold H then the wireless device processing complexity may increase above an acceptable level; otherwise, the wireless device processing complexity remains within an acceptable level. Examples of wireless device processing complexity are amount of memory size needed and amount or number of processors/processing units needed to decode the packet.

The second threshold H can be a semi-static or dynamic parameter depending on available resources such as memory, processors, and/or battery life of the wireless device. The wireless device typically uses a common pool of resources for reception/transmission of signals and other services. Therefore, the availability of resources and/or battery life may depend on whether the wireless device is also configured for performing or is performing another service, e.g., offline services etc., and/or procedures, e.g. positioning measurements, while decoding the packet. This is explained with the following examples:

In one example, the wireless device may transmit the information about H together with the decoder status or separately to the network node. For example, this approach may be used by the wireless device when H changes dynamically, e.g., when available wireless device resources change more often. In another example, the wireless device may transmit the information about H periodically or occasionally when H changes. In one example the wireless device may transmit H using the same channel, e.g., UL control channel such as PUCCH, as used for transmitting the decoder status to the network node. In another example, the wireless device may transmit H using higher layer signaling for example, using an RRC message. The latter may be used if H changes slowly, e.g., semi-statically.

The network node uses the received information about H for adapting one or more parameters used for transmitting the control data on the DCC, as explained in the following with some examples. For example, if the Np<H, then the network node may decide not to change the aggregation level compared to a reference value. As an example, the reference value can be the currently configured value/current value. Alternatively, the network node may decide to increase the aggregation level above the reference value. For example, if the Np H then the network node may decide to decrease the aggregation level compared to the reference value.

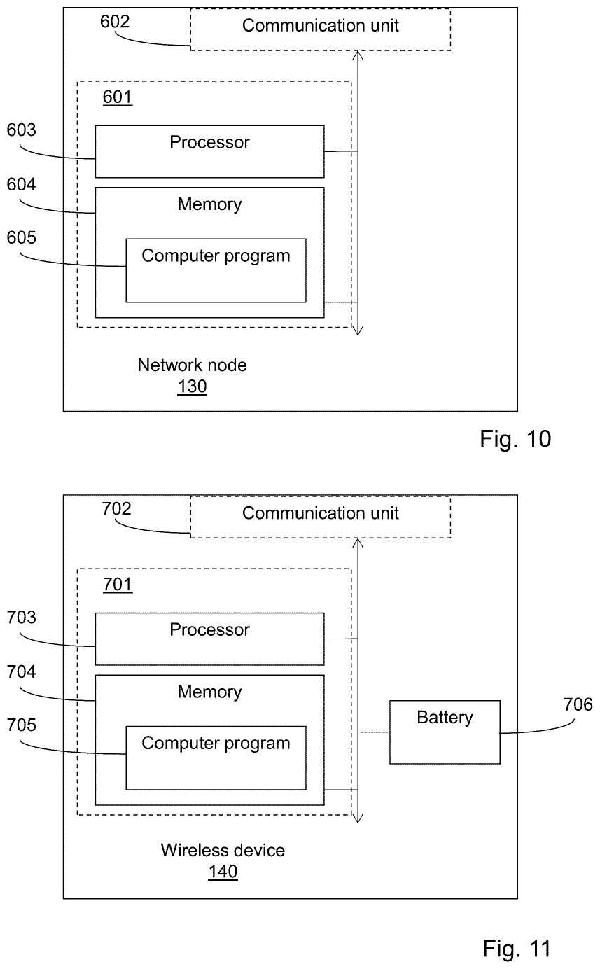

FIG. 10, in conjunction with FIG. 5, shows a network node 130 operable in a wireless communication network 100 configured for efficient usage of downlink transmission resources. The network node 130 comprises a processing circuitry 603 and a memory 604. Said memory contains instructions executable by said processing circuitry, whereby the network node 130 is operative for transmitting, to a wireless device 140, an encoded first control data packet on a downlink control channel using a first level of a transmission parameter, and receiving, from the wireless device 140, information on decoding status for the first control data packet transmitted on the downlink control channel using the first transmission parameter level, the decoding status being a quantitative measure of decoding complexity of the wireless device in decoding the first control data packet. The network node 130 is further operative for transmitting, to the wireless device 140, an encoded second control data packet on the downlink control channel using a second level of the transmission parameter, the second level being determined based on the received information on decoding status.

According to an embodiment, the network node 130 is further operative for determining the second level of the transmission parameter based on the received information on decoding status.

According to another embodiment, the transmission parameter is an encoding parameter used for the encoding of the first and second control data packet.

According to another embodiment, the second level of the encoding parameter is different from the first level of the encoding parameter, and the network node is further operative for, prior to the transmitting of the encoded second control data packet on the downlink control channel using the second level of the encoding parameter, transmitting information on the second level of the encoding parameter to the wireless device 140.

According to another embodiment, the received information on decoding status is information on list size, which is a number of candidate codewords that was used by the wireless device 140 for decoding the first control data packet.

According to yet another embodiment, the received information on list size is a bit value referring to a decoder status list look-up table with different bit values and corresponding list sizes and/or decoder types, which look-up table is obtainable by both the wireless device 140 and the network node 130.

According to yet another embodiment, the network node is further operative for transmitting a configuration message to the wireless device 140 with instructions to the wireless device how to send the information on decoding status to the network node 130.

According to yet another embodiment, the instructions of the configuration message comprise a decoding status threshold and an instruction to only send the information on the decoding status when the decoding status exceeds the decoding status threshold.

According to still another embodiment, the network node is further operative for receiving, from the wireless device, information on a device-capacity decoding status threshold related to which decoding status the wireless device can manage to decode.

According to another embodiment, the network node 130 has a polar encoder arranged for encoding the first and second control data packets.

According to other embodiments, the network node 130 may further comprise a communication unit 602, which may be considered to comprise conventional means for wireless communication with the wireless device 140, such as a transceiver for wireless transmission and reception of signals in the communication network. The communication unit 602 may also comprise conventional means for communication with other network nodes of the wireless communication network 100. The instructions executable by said processing circuitry 603 may be arranged as a computer program 605 stored e.g., in said memory 604. The processing circuitry 603 and the memory 604 may be arranged in a sub-arrangement 601. The sub-arrangement 601 may be a micro-processor and adequate software and storage therefore, a Programmable Logic Device, PLD, or other electronic component(s)/processing circuit(s) configured to perform the methods mentioned above. The processing circuitry 603 may comprise one or more programmable processor, application-specific integrated circuits, field programmable gate arrays or combinations of these adapted to execute instructions.

The computer program 605 may be arranged such that when its instructions are run in the processing circuitry, they cause the network node 130 to perform the steps described in any of the described embodiments of the network node 130 and its method. The computer program 605 may be carried by a computer program product connectable to the processing circuitry 603. The computer program product may be the memory 604, or at least arranged in the memory. The memory 604 may be realized as for example a RAM (Random-access memory), ROM (Read-Only Memory) or an EEPROM (Electrical Erasable Programmable ROM). In some embodiments, a carrier may contain the computer program 605. The carrier may be one of an electronic signal, an optical signal, an electromagnetic signal, a magnetic signal, an electric signal, a radio signal, a microwave signal, or computer readable storage medium. The computer-readable storage medium may be e.g. a CD, DVD or flash memory, from which the program could be downloaded into the memory 604. Alternatively, the computer program may be stored on a server or any other entity to which the network node 130 has access via the communication unit 602. The computer program 605 may then be downloaded from the server into the memory 604.

FIG. 11, in conjunction with FIG. 5, shows a wireless device 140 configured for connection to a wireless communication system 100. The wireless device 140 comprises a processing circuitry 703 and a memory 704. Said memory contains instructions executable by said processing circuitry, whereby the wireless device 140 is operative for receiving, from a network node 130 of the wireless communication network 100, an encoded first control data packet on a downlink control channel, the first control data packet being transmitted by the network node with a first level of a transmission parameter, and transmitting, to the network node 130, information on decoding status for the first control data packet received on the downlink control channel, the decoding status being a quantitative measure of decoding complexity of the wireless device in decoding the first control data packet. The wireless device is further operative for receiving, from the network node 140, an encoded second control data packet on the downlink control channel, the second control data packet being transmitted by the network node with a second level of the transmission parameter, the second level being based on the transmitted information on decoding status.

According to an embodiment, the wireless device 140 is further operative for, at decoding of the first control data packet, determining decoding status for the first control data packet.

According to another embodiment, the transmission parameter is an encoding parameter used for the encoding of the first and second control data packet.

According to another embodiment, the second level of the encoding parameter is different from the first level of the encoding parameter. The wireless device 140 is further operative for, prior to receiving the encoded second control data packet on the downlink control channel with the second level of the encoding parameter, receiving information on the second level of the encoding parameter from the network node 130.

According to another embodiment, the transmitted information on decoding status is information on list size, which is a number of candidate codewords that was used by the wireless device 140 for decoding the first control data packet.

According to yet another embodiment, the transmitted information on list size is a bit value referring to a decoder status list look-up table with different bit values and corresponding list sizes and/or decoder types, which look-up table is obtainable by both the wireless device 140 and the network node 130.

According to yet another embodiment, the wireless device 140 is further operative for receiving a configuration message from the network node 130 with instructions how to transmit the information on decoding status to the network node 130.

According to yet another embodiment, the instructions of the configuration message comprise a decoding status threshold and an instruction to only transmit the information on the decoding status when the decoding status exceeds the decoding status threshold.

According to still another embodiment, the wireless device 140 is further operative for transmitting, to the network node, information on a device-capacity decoding status threshold related to which decoding status the wireless device can manage to decode.

According to another embodiment, the wireless device 140 has a polar decoder arranged for decoding the first and second control data packets.

According to other embodiments, the wireless device 140 may further comprise a communication unit 702, which may be considered to comprise conventional means for wireless communication with the network node 130, such as a transceiver for wireless transmission and reception of signals in the communication network. The instructions executable by said processing circuitry 703 may be arranged as a computer program 705 stored e.g., in said memory 704. The processing circuitry 703 and the memory 704 may be arranged in a sub-arrangement 701. The sub-arrangement 701 may be a micro-processor and adequate software and storage therefore, a Programmable Logic Device, PLD, or other electronic component(s)/processing circuit(s) configured to perform the methods mentioned above. The processing circuitry 703 may comprise one or more programmable processor, application-specific integrated circuits, field programmable gate arrays or combinations of these adapted to execute instructions. The wireless device 140 may further comprise a battery 706 for providing electrical power to the device, such as to the processor 703 and the memory 704.

The computer program 705 may be arranged such that when its instructions are run in the processing circuitry, they cause the wireless device 140 to perform the steps described in any of the described embodiments of the wireless device 140 and its method. The computer program 705 may be carried by a computer program product connectable to the processing circuitry 703. The computer program product may be the memory 704, or at least arranged in the memory. The memory 704 may be realized as for example a RAM (Random-access memory), ROM (Read-Only Memory) or an EEPROM (Electrical Erasable Programmable ROM). In some embodiments, a carrier may contain the computer program 705. The carrier may be one of an electronic signal, an optical signal, an electromagnetic signal, a magnetic signal, an electric signal, a radio signal, a microwave signal, or computer readable storage medium. The computer-readable storage medium may be e.g. a CD, DVD or flash memory, from which the program could be downloaded into the memory 704. Alternatively, the computer program may be stored on a server or any other entity to which the wireless device 140 has access via the communication unit 702. The computer program 705 may then be downloaded from the server into the memory 704.

Although the description above contains a plurality of specificities, these should not be construed as limiting the scope of the concept described herein but as merely providing illustrations of some exemplifying embodiments of the described concept. It will be appreciated that the scope of the presently described concept fully encompasses other embodiments which may become obvious to those skilled in the art, and that the scope of the presently described concept is accordingly not to be limited. Reference to an element in the singular is not intended to mean “one and only one” unless explicitly so stated, but rather “one or more.” All structural and functional equivalents to the elements of the above-described embodiments that are known to those of ordinary skill in the art are expressly incorporated herein by reference and are intended to be encompassed hereby. Moreover, it is not necessary for an apparatus or method to address each and every problem sought to be solved by the presently described concept, for it to be encompassed hereby. In the exemplary figures, a broken line generally signifies that the feature within the broken line is optional.

1.-48. (canceled)

49. A method performed by a network node of a wireless communication network for efficient usage of downlink transmission resources, the method comprising:
transmitting, to a wireless device, an encoded first control data packet on a downlink control channel using a first level of a transmission parameter;
receiving, from the wireless device, information on decoding status for the first control data packet transmitted on the downlink control channel using the first transmission parameter level, the decoding status being a quantitative measure of decoding complexity of the wireless device in decoding the first control data packet, and
transmitting, to the wireless device, an encoded second control data packet on the downlink control channel using a second level of the transmission parameter, the second level being determined based on the received information on decoding status.

50. Method according to claim 49, further comprising:
determining the second level of the transmission parameter based on the received information on decoding status.

51. Method according to claim 49 wherein the transmission parameter is an encoding parameter used for the encoding of the first and second control data packet.

52. Method according to claim 51, wherein the second level of the encoding parameter is different from the first level of the encoding parameter, and the method further comprises, prior to the transmitting of the encoded second control data packet on the downlink control channel using the second level of the encoding parameter, transmitting information on the second level of the encoding parameter to the wireless device.

53. Method according to claim 49, wherein the received information on decoding status is information on list size, which is a number of candidate codewords that was used by the wireless device for decoding the first control data packet.

54. Method according to claim 53, wherein the received information on list size is a bit value referring to a decoder status list look-up table with different bit values and corresponding list sizes and/or decoder types, which look-up table is obtainable by both the wireless device and the network node.

55. Method according to claim 49, further comprising:
transmitting a configuration message to the wireless device with instructions to the wireless device how to send the information on decoding status to the network node, and wherein the instructions of the configuration message comprise a decoding status threshold and an instruction to only send the information on the decoding status when the decoding status exceeds the decoding status threshold.

56. Method according to claim 49, further comprising:
receiving, from the wireless device, information on a device-capacity decoding status threshold related to which decoding status the wireless device can manage to decode.

57. Method according to claim 49, wherein the network node has a polar encoder, and the method further comprises encoding the first and second control data packets using the polar encoder.

58. A method performed by a wireless device connected to a wireless communication network, the method comprising:
receiving, from a network node of the wireless communication network, an encoded first control data packet on a downlink control channel, the first control data packet being transmitted by the network node with a first level of a transmission parameter;
transmitting, to the network node, information on decoding status for the first control data packet received on the downlink control channel, the decoding status being a quantitative measure of decoding complexity of the wireless device in decoding the first control data packet, and
receiving, from the network node, an encoded second control data packet on the downlink control channel, the second control data packet being transmitted by the network node with a second level of the transmission parameter, the second level being based on the transmitted information on decoding status.

59. Method according to claim 58, further comprising, at decoding the first control data packet, determining decoding status for the first control data packet, and wherein the transmission parameter is an encoding parameter used for the encoding of the first and second control data packet.

60. A network node operable in a wireless communication network configured for efficient usage of downlink transmission resources, the network node comprising a processing circuitry and a memory, said memory containing instructions executable by said processing circuitry, whereby the network node is operative for:
transmitting, to a wireless device, an encoded first control data packet on a downlink control channel using a first level of a transmission parameter;
receiving, from the wireless device, information on decoding status for the first control data packet transmitted on the downlink control channel using the first transmission parameter level, the decoding status being a quantitative measure of decoding complexity of the wireless device in decoding the first control data packet, and
transmitting, to the wireless device, an encoded second control data packet on the downlink control channel using a second level of the transmission parameter, the second level being determined based on the received information on decoding status.

61. A wireless device configured for connection to a wireless communication system, the wireless device comprising a processing circuitry and a memory, said memory containing instructions executable by said processing circuitry, whereby the wireless device is operative for:
receiving, from a network node of the wireless communication network, an encoded first control data packet on a downlink control channel, the first control data packet being transmitted by the network node with a first level of a transmission parameter;
transmitting, to the network node, information on decoding status for the first control data packet received on the downlink control channel, the decoding status being a quantitative measure of decoding complexity of the wireless device in decoding the first control data packet, and receiving, from the network node, an encoded second control data packet on the downlink control channel, the second control data packet being transmitted by the network node with a second level of the transmission parameter, the second level being based on the transmitted information on decoding status.
